(19) United States
(12) Patent Application Publication
(10) Pub. No.: US 2012/0049839 A1
(43) Pub. Date: Mar. 1, 2012

(54) CIRCUIT-BREAKER WITH ROGOWSKI CURRENT TRANSFORMERS FOR MEASURING THE CURRENT IN THE CONDUCTORS OF THE CIRCUIT-BREAKER

(75) Inventor: Thomas Kiendl, Wernberg-Koblitz (DE)

(73) Assignee: SIEMENS AKTIENGESELLSCHAFT, Munich (DE)

(21) Appl. No.: 13/217,346

(22) Filed: Aug. 25, 2011

(30) Foreign Application Priority Data
Aug. 26, 2010 (DE) 102010039820.9

(51) Int. Cl. G01R 15/18

(52) U.S. Cl. 324/127

(57) ABSTRACT

A circuit-breaker is disclosed, in particular a low-voltage circuit breaker. In at least one embodiment, the circuit breaker includes a Rogowski current transformer for measuring a current in a conductor of the circuit-breaker, the Rogowski current transformer including at least three coil sections electrically connected in series and arranged to form a closed polygon, two coil sections in each case in the corner region of the closed polygon forming a joint region not taken in by the coil sections. In order to provide, for a circuit-breaker, an inexpensive current transformer with a high measuring accuracy which is made up of coil sections, in at least one embodiment at least one of the joint regions formed has a ferromagnetic material for shielding the joint region against magnetic interference fields.

### PRIORITY STATEMENT

The present application hereby claims priority under 35 U.S.C. §119 on German patent application number DE 10 2010 039 820.9 filed Aug. 26, 2010, the entire contents of which are hereby incorporated herein by reference.

### FIELD

At least one embodiment of the invention generally relates to a circuit-breaker, in particular a low-voltage circuit-breaker, which at least comprises a Rogowski current transformer for measuring a current in a conductor of the circuit-breaker, the Rogowski current transformer comprising at least three coil sections electrically connected in series and arranged to form a closed polygon, two coil sections (2) in each case in the corner region of the closed polygon forming a joint region not taken in by the coil sections.

### BACKGROUND

In the field of industrial automation engineering and building technology both protective functions and in future increasingly also precise measuring functions are called for in low-voltage circuit-breakers with an electronic trip unit. The protective function should be active both in multiphase and in single-phase operation of the circuit-breaker. Hence current transformers with an iron core come into consideration for supplying energy to an electronic trip unit of this type.

For saturation-free (i.e. absorption-free) measurement of the current in the conductors of a circuit-breaker use is preferably made of Rogowski current transformers (Rogowski coils). Rogowski current transformers are air gaps or current transformers with a core that possesses a permeability similar to air (relative permeability count μᵣ=1). The output signal of a Rogowski current transformer (a Rogowski coil) is a voltage that is proportional to the temporal change in the current through the conductor which the Rogowski current transformer (a Rogowski coil) completely encompasses.

EP 1 596 206 B1 discloses a current transformer for measuring the current in the conductors of a circuit-breaker which uses several coil sections (part-windings) electrically connected in series to measure the current.

### SUMMARY

At least one embodiment of the present invention, is directed to, for a circuit-breaker, an inexpensive current transformer, with a high measuring accuracy, which is made up of coil sections.

At least one embodiment is directed to a device, i.e. a circuit-breaker, in particular a low-voltage circuit breaker, which comprises at least one Rogowski current transformer for measuring a current of a conductor of the circuit-breaker, the Rogowski current transformer comprising at least three coil sections electrically connected in series and arranged to form a closed polygon, two coil sections in each case in the corner region of the closed polygon forming a joint region not taken in by the coil sections, at least one of the joint regions formed having a ferromagnetic material for shielding the joint region against magnetic interference fields.

Advantageous developments of the invention are specified in the dependent claims.

In a further advantageous embodiment of the invention, the ferromagnetic material completely covers the short side of a coil section.

### BRIEF DESCRIPTION OF THE DRAWINGS

In the following, the invention and the embodiment of the invention are described and explained in greater detail on the basis of the example embodiments shown in the figures.

FIG. 1 shows a diagrammatic design of a Rogowski current transformer made from straight coil sections without any shielding of the joint regions,

FIG. 2 shows a diagrammatic design of a Rogowski current transformer made from straight coil sections, the joint regions of the coil sections being filled with a ferromagnetic material,

FIG. 3 shows a diagrammatic design of an alternative embodiment of a Rogowski current transformer, the joint regions of the coil sections being filled with a ferromagnetic material,

FIG. 4 shows a diagrammatic design of a combined current transformer comprising a current transformer with iron core and a Rogowski current transformer, and

FIG. 5 shows a diagrammatic design of a circuit-breaker comprising a combined current transformer consisting of a current transformer with iron core and a Rogowski current transformer.

### DETAILED DESCRIPTION OF THE EXAMPLE EMBODIMENTS

Various example embodiments will now be described more fully with reference to the accompanying drawings in which only some example embodiments are shown. Specific structural and functional details disclosed herein are merely representative for purposes of describing example embodiments. The present invention, however, may be embodied in many alternate forms and should not be construed as limited to only the example embodiments set forth herein.

Accordingly, while example embodiments of the invention are capable of various modifications and alternative forms, embodiments thereof are shown by way of example in the drawings and will herein be described in detail. It should be understood, however, that there is no intent to limit example embodiments of the present invention to the particular forms disclosed. On the contrary, example embodiments are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments of the present invention. As used herein, the term “and/or,” includes any and all combinations of one or more of the associated listed items.

It will be understood that when an element is referred to as being “connected,” or “coupled,” to another element, it can be directly connected or coupled to the other element or intervening elements may be present. In contrast, when an element is referred to as being “directly connected,” or “directly coupled,” to another element, there are no intervening elements present. Other words used to describe the relationship between elements should be interpreted in a like fashion (e.g., “between,” versus “directly between,” “adjacent,” versus “directly adjacent,” etc.).

The terminology used herein is for the purpose of describing particular embodiments only and is not intended to be limiting of example embodiments of the invention. As used herein, the singular forms “a,” “an,” and “the,” are intended to include the plural forms as well, unless the context clearly indicates otherwise. As used herein, the terms “and/or” and “at least one of” include any and all combinations of one or more of the associated listed items. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Spatially relative terms, such as “beneath”, “below”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, term such as “below” can encompass both an orientation of above and below. The device may be otherwise oriented (rotated 90 degrees or at other orientations) and the spatially relative descriptors used herein are interpreted accordingly.

Although the terms first, second, etc. may be used herein to describe various elements, components, regions, layers and/or sections, it should be understood that these elements, components, regions, layers and/or sections should not be limited by these terms. These terms are used only to distinguish one element, component, region, layer, or section from another region, layer, or section. Thus, a first element, component, region, layer, or section discussed below could be termed a second element, component, region, layer, or section without departing from the teachings of the present invention.

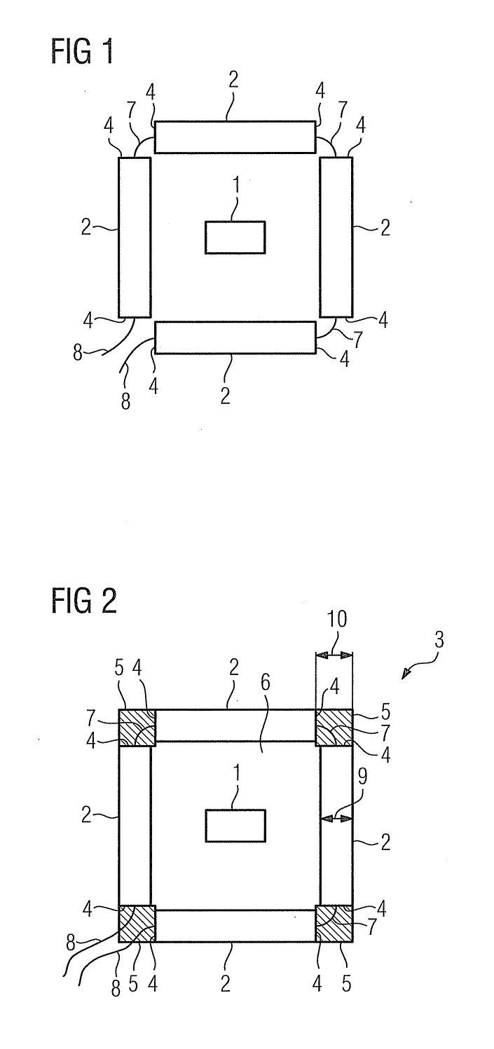

FIG. 1 shows a diagrammatic design of a Rogowski current transformer made from straight coil sections without any shielding of the joint regions. The Rogowski current transformer comprises four coil sections 2, with which a current flowing through a conductor 1 of a circuit-breaker can be determined. For this, a circuit-breaker includes the Rogowski current transformer. FIG. 1 shows the cross-section of a Rogowski current transformer.

In the Rogowski current transformer the coil sections 2 are electrically connected to one another in series. The individual coil sections 2 are, except for two ends 4 of the coil sections 2, electrically connected to one another by an electrical connection 7. The remaining two ends 4 of the coil sections 2 not connected to one another in each case have a connecting lead 8. Thus from a connecting lead 8 a continuous electrical connection exists via the individual coil sections 2 to the other connecting lead 8. Thanks to a voltage tap between the connecting leads 8 ultimately a voltage can be determined by an electronic evaluation unit of the circuit-breaker, which voltage is proportional to the temporal change in the current flowing through the conductor 1. From this voltage the electronic evaluation unit can determine the current flowing in the conductor 1 by means of integration.

Because the ends 4 of the respective coil sections 2 are open and are connected to one another merely via an electrical connection 7, an interference field and in particular a magnetic field is not determined at the same time in the region of the joint regions of the coil sections 2. The current flowing through the conductor is thus not determined precisely. Furthermore, a magnetic field can be generated by a conductor located outside this arrangement and through which current flows, so that current measurement using a current measuring device of this type is falsified or distorted. A precise measurement, free of external fields, of the current flowing through the conductor 1 thus cannot be guaranteed. The joint region is in particular in each case the corner region of the Rogowski current transformer not covered by a coil section 2.

FIG. 2 shows a diagrammatic design of a Rogowski current transformer 3 made from straight coil sections 2, the joint regions of the coil sections 2 being filled with a ferromagnetic material 5. This Rogowski current transformer 3 has, unlike the Rogowski current transformer in FIG. 1, a shielding at the respective joints of the ends 4 of the coil sections 2. The corner regions of the Rogowski current transformer not taken in by a coil section 2 here form the joint regions, which preferably are completely filled with a ferromagnetic material 5. The shielding against magnetic interference fields is formed by the ferromagnetic material 5. Because the joint regions of the coil sections 2 have a ferromagnetic material 5, this region is brought to an approximately constant magnetic potential. Only a very low magnetic field (magnetic H field) or a very low magnetic voltage can form in this region.

The Rogowski current transformer 3 resides in this example embodiment of four coil sections 2 which are arranged in a square. Inside the square arrangement of the coil sections 2 is an opening 6, through which a conductor 1 of the circuit-breaker is led. The current through this conductor 1 is measured by the Rogowski current transformer 3 and a down-stream electronic trip unit of the circuit-breaker. Thanks to a voltage tap at the connecting leads 8 a return path to the current flowing through the conductor 1 can ultimately be obtained. The shielding at the joint regions of the coil sections 2 is provided by a highly-permeable ferromagnetic material 5, for example nickel-iron, silicon-iron or ferrite.

The ferromagnetic material 5 is here dimensioned such that a sufficient shielding of the region around the joints of the coil sections 2 (of the joint region) or of the Rogowski current transformer 3 against magnetic fields is provided.

Thus only the magnetic field inside the coil sections 2 is taken into account by the Rogowski current transformer 3 when measuring current.

The coil sections 2 are connected in series to one another by an electrical connection 7.

The diameter or the diagonal 10 of the material 5 here has the same diameter or the same diagonal 9 as the adjacent coil section 2, so that preferably the short side of the coil section 2 is completely covered by the material 5. The material 5 should at least be dimensioned such that an appreciable shielding of the joint region of the coil sections 2 against magnetic fields and ultimately an improvement in the measuring result of the Rogowski current transformer 3 is effected.

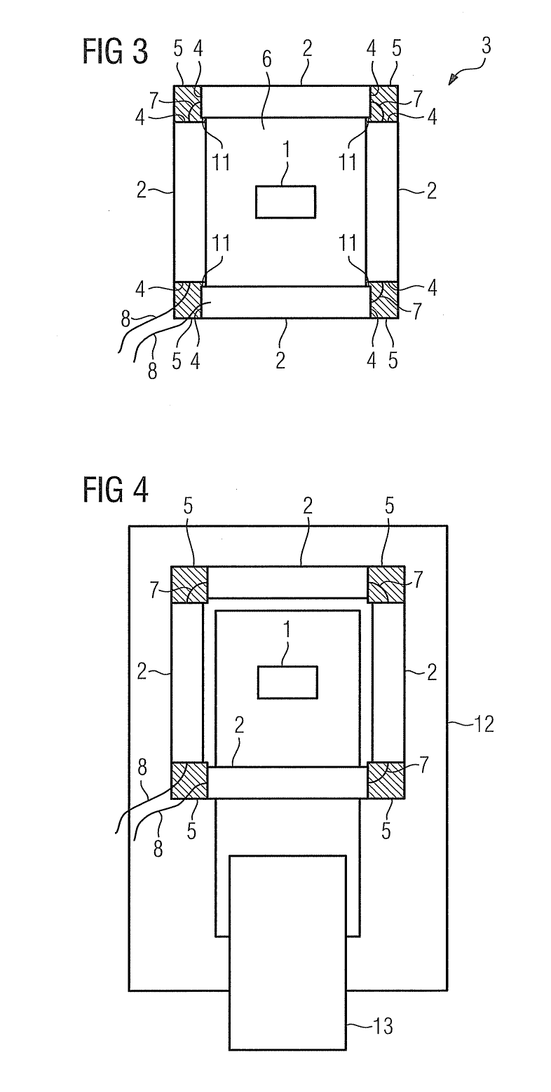

FIG. 3 shows a diagrammatic design of an alternative embodiment of a Rogowski current transformer 3, the joint regions of the coil sections 2 being filled with a ferromagnetic material 5. This Rogowski current transformer 3 in turn comprises four coil sections 2, which are connected in series to one another by electrical connections 7. The current flowing in the conductor 1 can ultimately be determined using two connecting leads 8. The coil sections 2 are here arranged such that an overlap 11 of a end 4 of a coil section 2 by the adjacent coil section 2 exists. An end 4 of a coil section 2 thus projects into the region of the short side of an adjacent coil section 2. The open region of the short side of the respective coil section 2 is in turn filled with a ferromagnetic material 5, so that a magnetic shielding is effected. The coil sections 2 are connected in series to one another by an electrical connection 7.

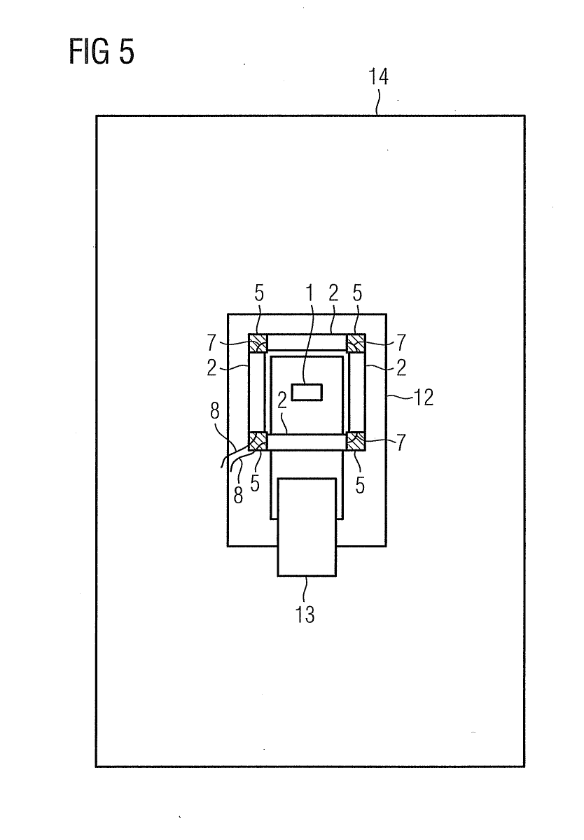

FIG. 4 shows a diagrammatic design of a combined current transformer comprising a current transformer with iron core 12 and a Rogowski current transformer. This combined current transformer comprises a Rogowski current transformer according to FIG. 2 for measuring the current of a conductor 1 of the circuit-breaker as well as a current transformer with iron core 12 for supplying an electronic trip unit of the circuit-breaker with energy. The current transformer with iron core 12 has an iron core 12 made from punched core sheets preferably made from silicon-iron, and a coil 13. The iron core 12 has an opening through which a conductor 1 of the circuit-breaker projects. With the help of the current transformer with iron core 12 the electronic trip unit of the circuit-breaker is supplied with energy. The energy is here obtained from the current which flows through the conductor 1.

Since the Rogowski current transformer has a ferromagnetic material 5 at all ends of the coil sections 2, a shielding in the joint region against magnetic fields can be provided and thus an improved measuring result of the Rogowski current transformer effected. The joint region is accordingly the region left open by two adjoining coil sections 2 around their joint. In particular the joint region, preferably completely filled by the ferromagnetic material 5, is in each case the corner region of the polygon formed by the Rogowski current transformer which is not taken in by a coil section 2.

Thanks to the design of a combination transformer of a circuit-breaker with a Rogowski current transformer of this type and an iron core current transformer an inexpensive circuit-breaker and in particular combination transformer can be enabled, whose Rogowski current transformer has an improved measuring accuracy thanks to the shielding. In this way the combination transformer of the circuit-breaker can be used not just for protective purposes, but also for precise measurement purposes.

FIG. 5 shows a diagrammatic design of a circuit-breaker 14 which includes a combined current transformer from FIG. 4. The current flowing in the conductor 1 of the circuit-breaker 14 is here determined using the Rogowski current transformer. An electronic trip unit of the circuit-breaker 14 is supplied with energy via the current transformer with iron core 12. In the event of an overcurrent or short-circuit current an opening of contacts is initiated by the electronic trip unit by activating an opening mechanism, preferably via a magnetic actuator, so that the current flowing across the conductor 1 is interrupted.

In FIGS. 2 to 5 the joint region is completely filled by the ferromagnetic material 5, so that the hatched region 5 characterized by the reference character 5 can likewise be employed to define the joint region.

Rogowski current transformers made of linear coil sections are significantly simpler and cheaper to produce than annular core Rogowski current transformers. The great disadvantage of Rogowski current transformers made of linear (straight) coil sections is that in the region of the joints (joint regions) of the linear coil sections the magnetic field generated by the current in the conductor under consideration is not completely detected and thus the current in the conductor cannot be precisely measured. Because of the undetected magnetic field at the joint regions of the conductors the output signal (the output voltage of the Rogowski coil) is furthermore significantly more heavily affected by magnetic interference fields. Interference fields are here in particular magnetic fields that are not generated by the current to be measured in the respective main current path (conductor) of the circuit-breaker. An example of the source and thus cause of this type of interference field is the currents in the adjoining poles of the circuit-breaker (external pole or external field interference).

Because of the ferromagnetic material the joint region (the region around the joints) is preferably brought to an approximately identical magnetic potential. The magnetic field strength (magnetic H field) or the magnetic voltage can be significantly reduced and brought approximately to zero in this region, which is not detected by the coil sections of the Rogowski current transformer, by introducing the ferromagnetic material.

Each coil section has two ends which are preferably arranged opposite one another. The end is preferably formed by the short side of the coil section, so that each coil section comprises two ends. When considering the closed polygon the joint region is defined in particular by the ends of the coil sections. In each case here a joint region abuts two ends of two adjoining coil sections. The joint region is thus preferably in each case the region which when considering a corner of the polygon is left open by the two coil sections. A joint and thus the joint region, which preferably comprises the ferromagnetic material, is defined by two adjacent ends of two adjoining coil sections.

Preferably all joint regions have a ferromagnetic material, so that shielding against magnetic interference fields occurs at all joint regions. The ferromagnetic material furthermore in each case preferably completely fills the joint regions, so that a complete shielding of the joint region against magnetic interference fields exists. It is likewise conceivable that merely one part of the joint region is filled with a ferromagnetic material, so that merely one part of the joint region is shielded against magnetic interference fields. The ferromagnetic material preferably at least partially overlaps the short sides of the adjacent coil sections.

A major advantage of such a current transformer is accordingly that by introducing a ferromagnetic material in the joint region only a very low magnetic H field or a very low magnetic voltage can form there. The magnetic H field of the conductor whose current is to be measured focuses almost completely on the region of the coil sections and is detected in full by the Rogowski current transformer. The Rogowski current transformer can thus be used for precise measurement purposes and not just for protection purposes in a circuit-breaker.

A coil section of the measuring system here preferably comprises a wound coil on a support made of a plastic with a permeability similar to air (μᵣ=1).

The circuit-breaker can here have a Rogowski current transformer of this type for each phase (conductor) to be monitored. For this, for each phase of the circuit-breaker to be monitored coil sections of the respective Rogowski current transformer are arranged around the corresponding conductor to be monitored, so that for each conductor to be monitored the current of this conductor can be determined by the corresponding Rogowski current transformer. A circuit-breaker which for example has three phases (conductors) to be monitored thus preferably comprises three separate Rogowski current transformers, which in each case are arranged with their coil sections around the conductor to be monitored.

In an advantageous embodiment of the invention the closed polygon has an opening, through which the conductor is led.

The opening is here preferably arranged centrally and the conductor of the circuit-breaker (primary circuit) is preferably located in the center of the polygon. The coil sections accordingly surround the conductor. When current flows through the conductor a voltage is induced in the coil sections which is proportional to the temporal change in the current in the conductor. The coil sections are electrically connected in series. Because the regions around the joints and thus the joint regions of the coil sections are shielded by a ferromagnetic material, the current of the conductor can be precisely measured using the Rogowski current transformer.

In a further advantageous embodiment of the invention, the current measuring device comprises four coil sections which are arranged such that they produce a closed shape.

In a further advantageous embodiment of the invention, the shape is a square or a rectangle. The four coil sections are accordingly arranged to form a square or a rectangle.

In a further advantageous embodiment of the invention, the respective coil section extends linearly. Linear (straight) coil sections accordingly exist.

In an imaginary extension of the outer long side facing away from the conductor and the inner long side facing the conductor of the respective coil section regions of intersection between the adjoining coil sections occur in each case at the corner region of the polygon. The respective joint region is in particular formed by this region of intersection so formed.

In a further advantageous embodiment of the invention, the coil section in each case forms an end on its short side and thus in each case has two preferably opposing ends, two ends of two coil sections forming a joint region in each case having a connecting lead, so that a voltage tap for determining the current of the conductor can occur via the connecting leads, and in each case the other ends of the coil sections forming a joint region are electrically connected to one another.

A closed measuring system is thus formed by the coil sections. Providing the measuring system (the Rogowski current transformers) for example consists of three coil sections, a connecting lead is connected to the first coil end of the first coil section and the second coil end of the first coil section is connected to the first coil end of the second coil section. The second coil end of the second coil section is connected to the first coil end of the third coil. The windings of the individual coil sections are thus connected in series. Ultimately the last coil section has the second connecting lead as an “output”, so that an electrical connection exists across the individual windings of the coil sections via the first and second connecting lead. A return path to the current flow of a conductor encircled by the coil sections can thus be created via a voltage tap between the connecting leads. This voltage signal is proportional to the temporal change in the current flowing in the conductor. Using a down-stream electronic trip unit of the circuit-breaker the current flow can ultimately be determined by integrating the Rogowski converter output voltage. Because the coil sections preferably have a shielding at all their ends and thus in the joint region, the current can be determined more precisely.

In a further advantageous embodiment of the invention, the material is dimensioned such that it has at least 50% of the maximum radial diameter of one of the adjacent coil sections.

The diameter or the diagonal should here be considered in respect of the linear axis of the coil section. The diameter or the diagonal of the material, also aligned to the linear axis, which is used for shielding an end of the coil section, is here preferably at least 50% of the maximum radial diameter or the maximum diagonal of the adjacent coil section.

In a further advantageous embodiment of the invention, the material is dimensioned such that a diameter of the material is greater than or equal to the maximum radial diameter of one of the adjacent coil sections.

The relation of the diameter of the material here always relates to the diameter of one of the adjacent coil sections. If the coil sections and/or the material is rectangular in shape, its diagonal should be considered.

In a further advantageous embodiment of the invention, the coil section in each case forms an end on its short side and thus in each case has two preferably opposing ends, at least one of the ends of a coil section being partly overlapped by the adjacent coil section.

The end of a coil section is accordingly arranged next to a short side of an adjacent coil section. In the event of an overlap the short side of a coil section is preferably completely overlapped by the long side of the adjoining coil section. An open short side of the coil section is here preferably completely overlapped by the shielding.

In a further advantageous embodiment of the invention, the coil section in each case forms an end on its short side and thus in each case has two preferably opposing ends, the coil sections being arranged such that no overlap of the adjacent ends of the coil sections by the coil sections themselves exists.

The long side of a coil section is accordingly not arranged next to a short side of the adjacent coil section. In the event of a square shape the coil sections accordingly in each case have the same length in respect of their long side.

In an advantageous embodiment of the invention, the shielding of the joint regions against magnetic interference fields by the ferromagnetic material is many times better than a shielding by air.

In a further advantageous embodiment of the invention, the ferromagnetic material is made of nickel-iron, silicon-iron, a highly-permeable material or a ferrite.

In a further advantageous embodiment of the invention, the ferromagnetic material is made up of individual laminated sheets made of nickel-iron, silicon-iron, a highly-permeable material or ferrite. The lamination means losses through eddy currents can be prevented.

In a further advantageous embodiment of the invention, the circuit-breaker comprises the Rogowski current transformer for measuring the current in the conductor and a current transformer with iron core for supplying energy to an electronic trip unit of the circuit-breaker.

The circuit-breaker thus comprises a combined current transformer (also known as a combination transformer). The combined current transformer consists of a current transformer with iron core and the Rogowski current transformer. The current transformer with iron core is used to supply energy to the electronic trip unit. The Rogowski current transformer supplies a voltage as an output signal, said voltage being proportional to the temporal change (derivation) in the current through the conductor which the combination transformer comprises. By analog or digital integration of the Rogowski current transformer output signal in the electronic trip unit of the circuit-breaker the current in the conductor can be determined from the output signal of the Rogowski current transformer. The current transformer with iron core can for example be an iron core-current transformer which has an annular iron core made from a cut strip-wound core or a rectangular iron core made from punched core sheets.

In a further advantageous embodiment of the invention, in each case the region of intersection of the extension of the axes of the coil sections has the ferromagnetic material.

In a further advantageous embodiment of the invention, the circuit-breaker comprises an opening mechanism for opening electrical contacts of the circuit-breaker and thus for interrupting the current flowing in the conductor.

In the event of an overcurrent or short-circuit current, an opening of contacts is initiated by the electronic trip unit by activating an opening mechanism, preferably via a magnetic actuator, so that the current flowing across the conductor is interrupted.

The patent claims filed with the application are formulation proposals without prejudice for obtaining more extensive patent protection. The applicant reserves the right to claim even further combinations of features previously disclosed only in the description and/or drawings.

The example embodiment or each example embodiment should not be understood as a restriction of the invention. Rather, numerous variations and modifications are possible in the context of the present disclosure, in particular those variants and combinations which can be inferred by the person skilled in the art with regard to achieving the object for example by combination or modification of individual features or elements or method steps that are described in connection with the general or specific part of the description and are contained in the claims and/or the drawings, and, by way of combinable features, lead to a new subject matter or to new method steps or sequences of method steps, including insofar as they concern production, testing and operating methods.

References back that are used in dependent claims indicate the further embodiment of the subject matter of the main claim by way of the features of the respective dependent claim; they should not be understood as dispensing with obtaining independent protection of the subject matter for the combinations of features in the referred-back dependent claims. Furthermore, with regard to interpreting the claims, where a feature is concretized in more specific detail in a subordinate claim, it should be assumed that such a restriction is not present in the respective preceding claims.

Since the subject matter of the dependent claims in relation to the prior art on the priority date may form separate and independent inventions, the applicant reserves the right to make them the subject matter of independent claims or divisional declarations. They may furthermore also contain independent inventions which have a configuration that is independent of the subject matters of the preceding dependent claims.

Further, elements and/or features of different example embodiments may be combined with each other and/or substituted for each other within the scope of this disclosure and appended claims.

Example embodiments being thus described, it will be obvious that the same may be varied in many ways. Such variations are not to be regarded as a departure from the spirit and scope of the present invention, and all such modifications as would be obvious to one skilled in the art are intended to be included within the scope of the following claims.

What is claimed is:

1. A circuit-breaker, comprising:
a Rogowski current transformer to measure a current in a conductor of the circuit-breaker, the Rogowski current transformer including
at least three coil sections electrically connected in series and arranged to form a closed polygon, two of the at least three coil sections, in a corner region of the closed polygon, forming at least one joint region not taken in by the at least three coil sections, at least one
joint region formed including a ferromagnetic material for shielding the joint region against magnetic interference fields.

2. The circuit-breaker as claimed in claim 1, wherein the closed polygon includes an opening through which the conductor is led.

3. The circuit-breaker as claimed in claim 1, wherein the current measuring device includes four coil sections which are arranged such that they produce a closed shape.

4. The circuit-breaker as claimed in claim 3, wherein the shape is a square or a rectangle.

5. The circuit-breaker as claimed in claim 1, wherein the coil sections extend linearly.

6. The circuit-breaker as claimed in claim 1, wherein each of the respective coil sections forms an end on its relatively short side, and thus includes two ends of two coil sections, each forming a respective joint region including a connecting lead, so that a voltage tap for determining the current in the conductor is provideable via the connecting leads, and wherein, in each case, other ends of the coil sections that form a joint region, are electrically connected to one another.

7. The circuit-breaker as claimed in claim 1, wherein the ferromagnetic material is dimensioned such that it has at least 50% of the maximum radial diameter of one of the adjacent coil sections.

8. The circuit-breaker as claimed in claim 1, wherein the ferromagnetic material is dimensioned such that a diameter of the ferromagnetic material is greater than or equal to the maximum radial diameter of one of the adjacent coil sections.

9. The circuit-breaker as claimed in claim 1, wherein each of the respective coil sections forms an end on its relatively short side, and thus includes two opposing ends, at least one of the ends of a coil section being partially overlapped by the adjacent coil section.

10. The circuit-breaker as claimed in claim 1, wherein each of the respective coil sections forms an end on its respectively short side, and thus includes two opposing ends, the coil sections being arranged such that no overlap of the adjacent ends of the coil sections by the coil sections themselves exists.

11. The circuit-breaker as claimed in claim 1, wherein the shielding is better than a shielding by air.

12. The circuit-breaker as claimed in claim 1, wherein the ferromagnetic material is made of nickel-iron, silicon-iron, a highly-permeable material or a ferrite.

13. The circuit-breaker as claimed in claim 1, wherein the ferromagnetic material is made up of individually laminated sheets made of nickel-iron, silicon-iron, a highly-permeable material or ferrite.

14. The circuit-breaker as claimed in claim 1, comprising the Rogowski current transformer for measuring the current in the conductor and a current transformer with iron core for supplying energy to an electronic trip unit of the circuit-breaker.

15. The circuit-breaker as claimed in claim 1, wherein a region of intersection of the extension of the axes of the coil sections, in each case, includes the ferromagnetic material.

16. The circuit-breaker as claimed in claim 1, further comprising an opening mechanism for opening electrical contacts of the circuit-breaker and thus for interrupting the current flowing in the conductor.

17. The circuit-breaker as claimed in claim 1, wherein the circuit-breaker is a low-voltage circuit breaker.
